(19) United States
(12) Patent Application Publication
(10) Pub. No.: US 2024/0044993 A1
(43) Pub. Date: Feb. 8, 2024

(54) Method and System for Type-Dependent Determination of a State of Health or of a State Variable Corresponding to a State of Health of a Battery Pack

(71) Applicant: Andreas Stihl AG & Co. KG, Waiblingen (DE)

(72) Inventors: Raphael WEGMANN, Leonberg (DE); Daniel SAUERTEIG, Kernen im Remstal (DE)

(21) Appl. No.: 18/229,844

(22) Filed: Aug. 3, 2023

(30) Foreign Application Priority Data
Aug. 4, 2022 (EP) 22188797.9

(51) Int. Cl. G01R 31/392; G01R 31/367; H02J 7/00

(52) U.S. Cl. CPC G01R 31/392; G01R 31/367; H02J 7/005; H02J 7/007182

(57) ABSTRACT

A method is provided for type-dependent determination of a state of health or a state variable corresponding to a state of health, of a battery pack for supplying an electrically powered processing device with electric drive power. The battery pack and a charging device are mutually coupleable for the supply of the battery pack with the electric charging power. The charging device is from a set of different types of charging devices. The method recognizes a type of the coupled charging device, particularly by way of the battery pack, and determines the state of health or the state variable in dependence of the type thus recognized, particularly by way of the battery pack.

### CROSS REFERENCE TO RELATED APPLICATION

This application claims priority under 35 U.S.C. § 119 from European Patent Application No. 22188797.9, filed Aug. 4, 2022, the entire disclosure of which is herein expressly incorporated by reference.

### BACKGROUND AND SUMMARY

The invention relates to a method and a system, particularly for the type-dependent determination of a state of health or of a state variable corresponding to a state of health of a battery pack.

The object of the invention is the provision of a method and a system for the type-dependent determination of a state of health or of a state variable corresponding to a state of health of a battery pack, particularly having respectively improved properties.

This object is fulfilled according to the invention by the provision of a method and a system described in the independent claims. Advantageous further developments and/or configurations of the invention are described in the dependent claims.

The method according to the invention is provided for the type-dependent determination of a state of health or of a state variable, particularly of a physical state variable corresponding to a state of health of a battery pack for the supply of an electrically powered processing device with electric drive power. The battery pack and a charging device for the supply of the battery pack with electric charging power are mutually coupleable and, in particular, are coupled. The charging device is, in particular, selected from a set of different types of charging devices. The method comprises the following steps: a) recognition of a type of coupled charging device, particularly by means of the battery pack; b) determination, in particular, either of the state of health or of the state variable in dependence of the type thus recognized, particularly by means of the battery pack.

This permits the state of health or state variable, in particular, to be determined in a progressive manner, thus permitting, in particular, both the current and/or the consolidated identification thereof, particularly at all times and for all types, or in the event of a change back-and-forth between different types.

In particular, the method, supply, recognition and/or determination can be executed automatically.

The term “variants” can be employed synonymously for the term “types”.

The term “state of ageing” can be employed synonymously for the term “state of health”.

The state of health can be a state of health or the state variable can be a state variable of battery cells of a battery pack.

The state of health or state variable can assume a value.

The term “having” or the term “incorporating” can be employed synonymously for the term “comprising”.

A unit of the state of health or the state variable can be percentage points.

The state variable can be a remaining capacity or residual capacity of the battery pack expressed as a % value (percentage) of an original capacity or nominal capacity of the battery pack. In particular, the capacity can be a charging capacity.

Typically, the state of health at a time of manufacture of the battery pack can be 100% and, over time and the progressive use of the battery pack, can fall, reduce or decline. In other words: the capacity of a battery pack over time, even in the event of proper use, can decline as a result of chemical reactions. This can also be described as degradation.

The battery pack, the processing device and/or the charging device can be mobile or portable. In particular, the term mobile can describe a mass not exceeding 50 kg (kilograms), particularly not exceeding 20 kg, particularly not exceeding 10 kg, particularly not exceeding 5 kg and/or of at 0.2 kg, particularly at least 0.5 kg, particularly at least 1 kg and particularly at least 2 kg.

The battery pack can comprise a plurality of battery cells. In particular, each of the battery cells can comprise individual rechargeable elements for the electrochemical storage of electrical energy. Additionally or alternatively, the battery cells can be lithium-ion accumulator cells. Further additionally or alternatively, the battery cells can be identical, particularly of an identical type or design. Further additionally or alternatively, a respective cell voltage, particularly a nominal cell voltage of a cell, particularly of a respective battery cell can be at least 2 V (volts) and/or a maximum of 4.2 V, particularly 3.6 V. Further additionally or alternatively, the battery cells can be cylindrical cells, prismatic cells or pouch cells.

The drive power can be employed for discharging the battery pack. Additionally or alternatively, charging power can be employed for charging the battery pack.

The processing device can comprise a processing tool and/or particularly an electric drive motor, in particular for driving the processing tool. In particular, drive power can be employed for the drive motor. Additionally or alternatively, the processing device can be a ground-running and/or walk-behind device, particularly hand-held, and can be a garden, woodland, agricultural and/or soil processing device. In particular, the processing device can be a saw, particularly a chainsaw, or a pruner, or a hedge cutter, or a hedge trimmer, or a woodcutter, or a branch trimmer, a power cutter, or a blowing device, or a leaf blower, or an aspirating device, or a leaf aspirator, or a cleaning device, or a pressure washer, or a sweeping device, or a sweeping roller, or a sweeping brush, or a lawnmower, or a grass trimmer, or a brush cutter, or a scarifier.

The charging device can be electrical.

The terminological element “pair” can be employed synonymously with the terminological element “couple”.

The battery pack and the charging device or processing device can be electrically connectable.

The coupling, particularly the electrical connection, can be releasable, particularly without the use of tools and/or in a non-destructive manner, particularly by a user.

The battery pack and the charging device or processing device can be mechanically connectable and releasable, particularly without the use of tools and/or in a non-destructive manner.

The battery pack and the charging device or processing device can be configured for the removal and/or replacement of the battery pack, particularly by the user. In particular, the charging device or processing device can comprise a battery compartment, wherein the battery compartment can be configured to accommodate the battery pack.

The term “designed” can be employed synonymously with the term “configured”.

At a given time point, in particular, either the battery back and the charging device of one type, or the battery pack and the charging device of another type or, in particular, the battery pack and the processing device can be mutually coupled.

Step a) can be executed chronologically in conjunction with and/or subsequently to coupling, particularly to a release of the coupling. Additionally or alternatively, step b) can be executed chronologically in conjunction with and/or subsequently to coupling, and/or further to step a) and/or sequentially to step a).

The method can comprise the supply of charging power, particularly during coupling.

In a further development of the invention, step b) comprises the following: determination of the state of health or state variable on the basis of an at least intermittently supplied charging variable, particularly of a charge. This permits the effective determination of the state of health or the state variable. In particular, the charging variable can assume a value and/or can be electrical. Additionally or alternatively, a unit of charge Ah (ampere-hours) and/or As (ampere-seconds) can be employed. Further additionally or alternatively, the term “quantity of charge” can be employed synonymously with the term “charge”. Further additionally or alternatively, step b) can comprise the following, for one type of charging device and, in particular, not for another type of charging device: determination of the state of health or the state variable on the basis of the only intermittently supplied charging variable, particularly the partial charge of Ah or quantity of charge. Further additionally or alternatively, for another type of charging device, step b) can comprise the following and, in particular, not for the first type of charging device: determination of the state of health or the state variable on the basis of a continuously supplied charging variable, particularly the full or total charge of Ah or quantity of charge.

In one configuration of the invention, the method comprises the following step: detection of a charging current for the charging variable, particularly by means of the charging device. This permits the determination of the charging variable, particularly by means of the method. In particular, detection can be automatic. Additionally or alternatively, the term “measurement” can be employed synonymously with the term “detection”. Further additionally or alternatively, the charging current can assume a value and/or can be electrical. Further additionally or alternatively, a unit of the charging current can be an ampere (A).

In a further development, particularly according to one configuration of the invention, determination of the state of health or state variable, or step b), differs for different types of charging devices, at least in part, and particularly in full. In particular, for one type of charging devices, step b) comprises the following and, in particular, not for another type of charging devices: determination of the state of health or state variable on the basis of the charging variable and a margin, particularly a difference, between state-of-charge variables, particularly states of charge of the battery pack temporally in advance of or subsequently to the supply thereof with the charging variable, particularly in the event of a respective reduction in the charging current, particularly in the absence of a charging current. This permits the state of health or state variable, particularly on the grounds of the minor or non-existent corruption of state-of-charge variables in the event of a reduction in charging current, to be determined in a particularly effective manner, particularly in the form of a capability for the accommodation of charge and/or for the employment of the first type. In particular, for the other type, such determination of the state of health or state variable and/or the reduction of the charging current, in particular the absence of charging current, will not be possible. Additionally or alternatively, the difference and/or the state-of-charge variables can assume a value and/or can be electrical. Further additionally or alternatively, the charging variable can be only intermittently supplied. Further additionally or alternatively, the reduction in the charging current is, or can be stipulated. Further additionally or alternatively, the terminological element “lack” can be employed synonymously with the terminological element “absence”. Further additionally or alternatively, an absence of charging current can signify a break in power and/or in charging, and/or a completion and/or termination of current and/or of charging.

In one configuration of the invention, the method comprises the following step, particularly for one type and/or not for the other type: detection of a voltage for the state-of-charge variable and/or for the reduction in charging current, particularly by means of the battery pack. This permits the state-of-charge variable to be determined and/or the reduction in the charging current to be stipulated, particularly by means of the method. In particular, detection can be automatic. Additionally or alternatively, the voltage can assume a value and/or can be electrical. Further additionally or alternatively, the voltage can be a voltage of at least one battery cell, particularly of all the battery cells in the battery pack.

In a further development, particularly according to one configuration of the invention, the method comprises the following step for one type of charging devices and, in particular, not for another type of charging devices: stipulation of the supply of charging power, particularly for the reduction in the charging current, in dependence the type recognized, and particularly in dependence of the voltage detected, particularly by means of the battery pack. This permits the state of health or status variable to be determined in a particularly effective manner. In particular, for another type, such stipulation cannot be possible. Additionally or alternatively, stipulation can be automatic. Further additionally or alternatively, stipulation can particularly comprise the following: initiation of a reduction in the charging current, particularly of an absence of charging current or a break in charging, and/or an adjustment of the charging current or charging currents.

In a further development of the invention, types included in an, in particular, type-specific command structure are at least partially and, in particular, entirely different. Additionally or alternatively, the type recognition function comprises a recognition and/or non-recognition function for the command structure of the charging device, particularly the recognition and/or non-recognition of the command structure. Further additionally or alternatively, the recognized type comprises a recognized and/or non-recognized command structure, particularly is the recognized and/or non-recognized command structure. In particular, the terminological element “order” can be employed synonymously with the terminological element “command”. In particular, the terminological element “layout” can be employed synonymously with the terminological element “command”. Further additionally or alternatively, one of the types can comprise the command structure, and another type not. Further additionally or alternatively, the command structure can be employed for communication.

In a further development, particularly according to one configuration of the invention, the method comprises the following step: communication between the battery pack and the charging device, particularly of the charging variable, the charging current, the stipulated supply of charging power, and/or of a command delivered by the command structure. This permits the determination of the state of health or the state variable and/or the execution of type recognition. In particular, communication can be automatic.

Coupling can be inductive and/or contactless.

In a further development, particularly according to one configuration of the invention, the battery pack and the charging device comprise detachable electric power contacts for the supply of charging power and, in particular, detachable electric communication contacts for communication. Coupling is permitted accordingly. In particular, coupling can be non-inductive and/or executed by contact and, in particular, communication contacts can be configured for mutual contact. Additionally or alternatively, the power contacts, and particularly the communication contacts, can comprise and, in particular, can be formed by plug connectors. Further additionally or alternatively, the terminological element “terminal” can be employed synonymously with the terminological element “contact”. Further additionally or alternatively, the power contacts, and particularly the communication contacts, can be detachable by the user, or user-detachable. Further additionally or alternatively, the communication contacts can partially differ from the power contacts.

In a further development, particularly according to one configuration of the invention, the method comprises the following step: saving, in particular, either of the state of health determined or of the state variable determined and, in particular, of the charging variable, of the charging current detected, of the state-of-charge variable, of the voltage detected and/or of the type recognized, particularly by means of the battery pack or in the battery pack. In particular, saving can be automatic.

In one configuration of the invention, the method comprises the following: in the event of a newly-determined state of health or newly-determined state variable which is greater than the saved state of health or the saved state variable, the saved state of health or saved state variable is not overwritten, or continues to be saved, and/or the newly-determined state of health or newly-determined state variable is not saved. This permits the state of health or state variable to be maintained up to date and/or consolidated. In particular, in the event that the newly-determined state of health or newly-determined state variable is equal to or smaller than the saved state of health or saved state variable, the saved state of health or the saved state variable is overwritten, and/or the newly-determined state of health or the newly-determined state variable can be saved. Additionally or alternatively, this can be executed by means of a mutual comparison, particularly according to the method, of the newly-determined state of health and the saved state of health, or a mutual comparison of the newly-determined state variable and the saved state variable, particularly by means of the battery pack.

In a further development of the invention, the method comprises the following step: the output and/or, in particular, wireless transmission of, in particular, user-perceptible information regarding, in particular, either the determined state of health or the determined state variable, particularly by means of the battery pack, the charging device and/or the processing device, particularly during coupling. This permits the perception of the state of health or the state variable, particularly by the user. Additionally or alternatively, this can be achieved by saving the state of health or the state variable. In particular, output and/or transmission can be automatic. Additionally or alternatively, transmission can be executed from the battery pack, the charging device and/or the processing device to an app and/or to an, in particular, portable terminal device and, in particular, from the terminal device to a database. In particular, the terminal device can be handheld and/or can be a laptop, a tablet or a smartphone. Further additionally or alternatively, transmission can be executed by means of Bluetooth and/or a WLAN. Further additionally or alternatively, the term “cordless” or “contactless” can be employed synonymously with the term “wireless”. Further additionally or alternatively, the term “by means of” can be employed synonymously with the wording “on the basis of”. Further additionally or alternatively, the information can comprise and, in particular, can be formed by a content, particularly a value, and/or the state of health or state variable.

In a further development, particularly according to one configuration of the invention, the execution of step a) is triggered by coupling, particularly by the formation of a coupling. Additionally or alternatively, in particular, step b) and, in particular, detection of the charging current and/or of the voltage, stipulation of the supply of charging power, communication between the battery pack and the charging device, saving of the determined state of health or the determined state variable, and/or the output and/or transmission of information, is executed again, particularly a plurality of times. This permits the state of health or state variable, particularly in a progressive manner, to be determined and/or maintained up-to-date and/or consolidated. In particular, the term “repeatedly” or “cyclically” can be employed synonymously with the term “again”.

The system according to the invention is particularly configured for a, particularly for the type-dependent determination of a, particularly of the state of health, or of a, particularly of the state variable corresponding to the state of health of a, particularly of the battery pack for the supply of electric drive power to a, particularly to the electrically powered processing device. The battery pack and a, particularly the charging device can be mutually coupled for the supply of electric charging power to the battery pack. The charging device is from a, particularly the set of different types charging devices. The system, particularly the battery pack, comprises a recognition device and a determination device. The recognition device is configured for the recognition of a, particularly of the type of coupled charging device, particularly by means of the battery pack. The determination device is configured for a, particularly for the determination of the state of health or of the state variable, in dependence of the type thus recognized, particularly by means of the battery pack. In particular, the system can be configured for the, in particular, automatic execution of a, particularly of the method, as described above. Additionally or alternatively, the system, the recognition device and/or the determination device can be electrical.

In a further development of the invention, the system comprises the following: the battery pack and/or the charging device and, in particular, the processing device. In particular, the system can comprise the terminal device and, in particular, the database. Additionally or alternatively, the battery pack, the charging device, the processing device, the terminal device and/or the database can be configured for the execution of the method.

Other objects, advantages and novel features of the present invention will become apparent from the following detailed description of one or more preferred embodiments when considered in conjunction with the accompanying drawings.

### BRIEF DESCRIPTION OF THE DRAWINGS

FIG. 1 is a schematic representation of a system according to an embodiment of the invention, comprising a battery pack and an electrically powered processing device;

FIG. 2 is a schematic representation of the system according to FIG. 1, comprising the battery pack and the charging device;

FIG. 3 is a schematic representation of the system according to FIG. 2, comprising the charging device of one type, and an exemplary method according to the invention for the type-dependent determination of a state of health, or of a state variable corresponding to the state of health of the battery pack;

FIG. 4 is a schematic representation of the system according to FIG. 2, comprising the charging device of a different type, and the exemplary method according to the invention for the type-dependent determination of the state of health or state variable; and

FIG. 5 is a schematic representation of the method according to FIGS. 3 and 4.

### DETAILED DESCRIPTION OF THE DRAWINGS

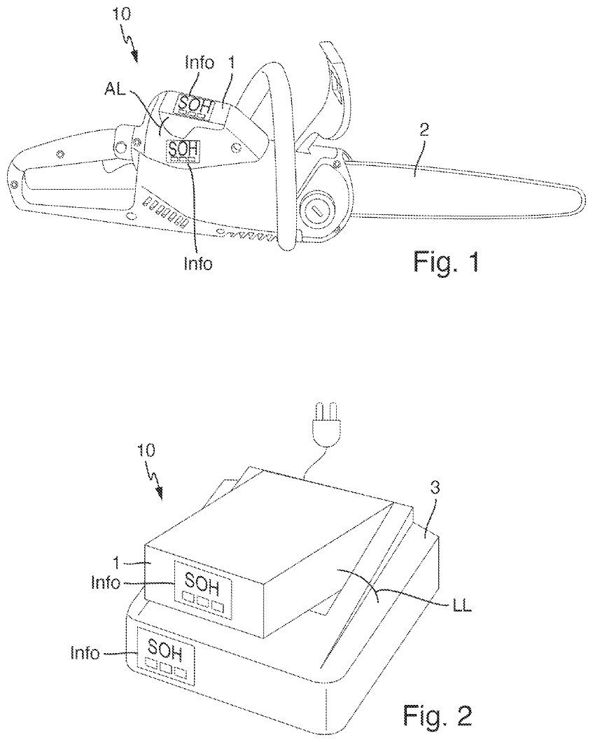

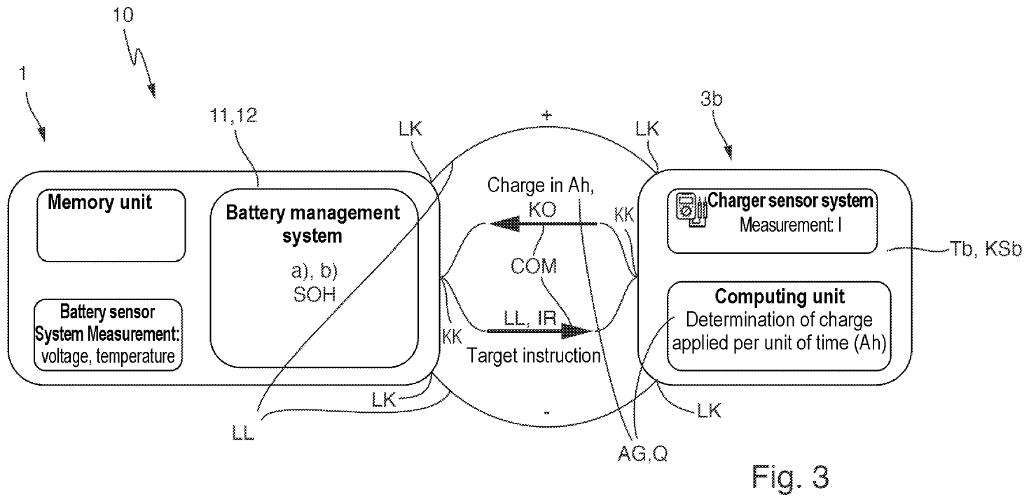

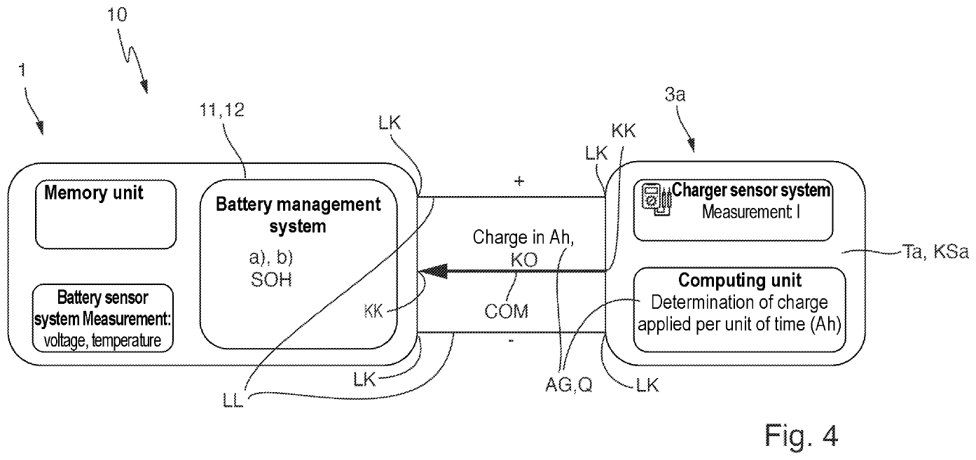

FIGS. 1 to 5 show a system 10 and a method for the type-dependent determination of a state of health SOH or of a state variable corresponding to a state of health, of a battery pack 1 for the supply of an electrically powered processing device 2 with electric drive power AL, as represented in FIG. 1. The battery pack 1 and a charging device 3 are mutually coupleable for the supply of the battery pack 1 with electric charging power LL and, in particular, are coupled, as represented in FIG. 2. The charging device 3 is from a set of different types Ta, Tb of charging devices 3a, 3b, as represented in FIGS. 3 to 5.

The system 10 comprises a recognition device 11 and a determination device 12. The recognition device 11 is configured for the recognition of and, in particular, recognizes a type Ta, Tb of the coupled charging device, particularly by means of the battery pack 1. The determination device 12 is configured for the determination of and, in particular, determines the state of health SOH or of the state variable, in dependence of the type Ta, Tb thus recognized, particularly by means of the battery pack.

The method comprises the following steps: a) recognition of a type Ta, Tb of coupled charging device 3a, 3b, particularly by means of the battery pack 1 and/or the recognition device 11; b) determination of the state of health SOH or of the state variable in dependence of the type Ta, Tb thus recognized, particularly by means of the battery pack 1 and/or the determination device 12.

In the exemplary embodiment represented, the battery pack 1 comprises a battery management system. The battery management system comprises the recognition device 11 and the determination device 12.

In detail, the system 10 comprises the following: the battery pack 1 and/or the charging device 3 and, in particular, the processing device 2.

Step b) moreover comprises the following: determination of the state of health SOH on the basis of an at least intermittently supplied charging variable AG, particularly of a charge Q.

In detail, the method comprises the following step: detection of a charging current I for the charging variable AG, particularly by means of the charging device 3, particularly a sensor system of the charging device 3.

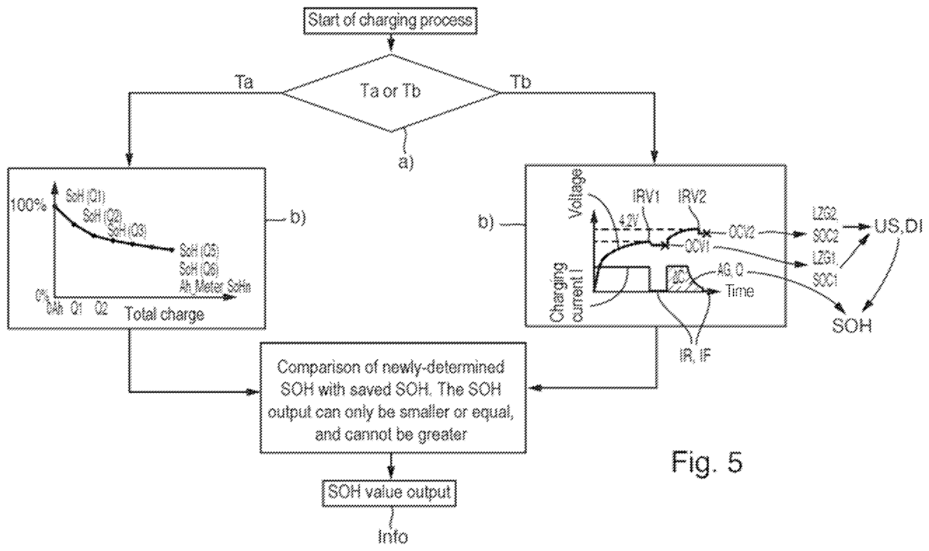

Moreover, determination of the state of health SOH or state variable for the different types Ta, Tb of charging devices 3a, 3b is at least partially different. In particular, step b), for one type Tb of charging devices 3b, comprises the following and, in particular, for another type Ta of charging devices 3a, does not, as represented in FIG. 5: determination of the state of health SOH or state variable on the basis of the charging variable AG and a margin US, particularly a difference DI between state-of-charge variables LZG1, LZG2, particularly states of charge SOC1, SOC2 of the battery pack 1 temporally in advance of and subsequently to the supply of the charging variable AG, particularly, in each case, with a charging current reduction IR, particularly an absence of charging current IF.

In detail, the method comprises the following step: detection of a voltage OCV1, OCV2, IRV1, IRV2 for the state-of-charge variables LZG1, LZG2 and/or for the charging current reduction IR, particularly by means of the battery pack 1, particularly a sensor system of the battery pack 1.

The method further comprises the following step for one type Tb of charging devices 3b and, in particular, for the other type Ta of charging devices 3a, does not, as represented in FIGS. 3 and 5: stipulation of supply with the charging power LL, particularly for the charging current reduction IR, in dependence of the recognition of type Tb and, in particular, the detected voltage IRV1, IRV2, particularly by means of the battery pack 1, particularly the battery management system.

Moreover, types Ta, Tb in a command structure KSa, KSb are at least partially different. Additionally or alternatively, recognition of type Ta, Tb comprises and, in particular, is the recognition of the command structure KSa, KSb of the charging device 3a, 3b. Further additionally or alternatively, the recognized type Ta, Tb comprises and, in particular, is a recognized command structure KSa, KSb.

The method further comprises the following step: communication between the battery pack 1 and the charging device 3, particularly of the charging variable AG, the charging current, the stipulation for supply with the charging power LL and/or a command KO from the command structure KS, particularly by means of a communication device, particularly of the battery management system of the battery pack 1, and a communication device of the charging device 3.

In the exemplary embodiment represented, the charging variable AG and/or the command KO from the command structure KS is/are communicated from the charging device 3 to the battery pack 1. Additionally or alternatively, the stipulation for supply with the charging power LL is communicated from the battery pack 1 to the charging device 3b of the first type Tb.

The battery pack 1 and the charging device 3 moreover comprise detachable electric power contacts LK for the supply of the charging power LL and, in particular, detachable electric communication contacts KK for communication.

The method further comprises the following step: saving of the determined state of health SOH or the determined state variable and, in particular, of the charging variable AG, the detected charging current, the state-of-charge variable, the detected voltage OCV1, OCV2 and/or the recognized type, particularly by means of the battery pack 1, particularly a memory unit of the battery pack 1.

In detail, the method comprises the following: in the event of a newly-determined state of health SOH or newly-determined state variable which is greater than a saved state of health SOH or saved state variable, the saved state of health SOH or saved state variable is not overwritten, and/or the newly-determined state of health SOH or the newly-determined state variable is not saved.

The method further comprises the following step: the output and/or, in particular, wireless transmission of, in particular, user-perceptible information Info regarding the determined state of health SOH or the determined state variable, particularly by means of the battery pack 1, the charging device 3 and/or the processing device 2, particularly an output and/or transmission device of the battery pack 1, the charging device 3 and/or the processing device 2.

In the exemplary embodiment represented, information Info is communicated to a user via a Bluetooth interface of a terminal device, particularly of a mobile phone, and/or via a portal to a software of the system 10.

Moreover, the execution of step a) is triggered by coupling. Additionally or alternatively, in particular, step b), in particular the detection of the charging current I and/or of the voltage OCV1, OCV2, IRV1, IRV2, stipulation of the supply of charging power LL, communication between the battery pack 1 and the charging device 3, saving of the determined state of health SOH or the determined state variable, and/or the output and/or transmission of information Info, is executed again.

In other words: SOH determination, for one type Tb of charging device 3b, can be executed by the cooperation or interaction of the battery pack 1 and the charging device 3b. For this charging device 3b, the battery pack 1 dictates the target instruction which is to be executed by the charging device 3b.

For another type Ta of charging device 3a, SOH determination can be executed by means of the battery pack 1.

Initially, for the commencement of the charging method or process (with the battery pack 1 plugged into the charging device 3), the battery pack 1 recognizes, by means of communication or COM, that the charging device 3a, 3b is of one type Tb or of the other type Ta.

In conjunction with, or during the charging process, by means of communication COM, relevant data for SOH determination are communicated or transmitted cyclically from the charging device 3 to the battery pack 1, including e.g. the charge in Ah (expressed in small time increments).

Data communicated from the battery pack 1 to the charging device 3, for the other type Tb of charging device 3b, are not data for SOH determination or the SOH function and, for one type Ta of charging device 3a, comprise a target current instruction.

For the other type Ta of charging device 3a, the battery pack 1 logs the total charge of Ah in the memory unit. On the basis of, or with reference to the charge in Ah, by means of an, in particular static data source for the SOH function, in this case a look-up table which, in particular, is saved in the memory unit, the current state of health/SOH value is determined or calculated, particularly in the battery pack 1. However, a query is executed as to whether this SOH value is lower than, or equal to the saved or previously determined SOH value. If the newly-determined or currently determined SOH value is greater, this will not be permitted, and the total charge in Ah saved in the battery pack 1 will be set such that the saved or previously determined SOH value will be in force.

For one type Tb of charging device 3b, the voltages OCV1 and OCV2 are saved in the memory unit, at respective time points during power breaks. Moreover, the charge Q in Ah which is introduced between OCV1 and OCV2, or during breaks, is saved in the memory unit. Moreover, an, in particular static data source for the SOH function is saved, particularly in the memory unit, for the voltage IRV1 with effect from which break 1 is to be initiated, when break 1 is to be terminated, the voltage IRV2 with effect from which break 2 is to be initiated, when break 2 is to be terminated, how the states of charge SOC1 and SOC2 can be inferred from the detected voltages OCV1 and OCV2, and how the SOH value can be inferred from the states of charge SOC1 and SOC2 and the charge Q, or how the SOH value can be calculated. In other words: in conjunction with, or during the charging process, the battery pack 1 initiates a break 1 (with the current set to 0 A). After a specific time interval (according to the data record), the voltage is determined from this break and saved (OCV1). The charging process continues until the completion of charging—defined by the end-of-charge voltage and the cut-off current—is achieved. Further to a specific time interval (according to the data record) following the completion of charging, the second voltage (OCV2) is determined. From OCV1 and OCV2, by means of the data record which is saved in the battery pack 1, the respective states of charge SOC1 and SOC2 which are assumed by the battery pack 1 at the end of the break times can be determined. The charge Q applied between the breaks OCV1 and OCV2 is also available to the battery pack 1. From this charge Q, and the states of charge SOC1 and SOC2 determined from the values for OCV1 and OCV2, the battery management system calculates the current SOH value. Here again, a query is executed as to whether this SOH value is lower than, or equal to the saved or previously determined SOH value. If the newly-determined or currently determined SOH value is greater, this will not be permitted, and the total charge in Ah saved in the battery pack 1 will be set such that the saved or previously determined SOH value will be in force.

If, according to the method for one type Tb of charging device 3b, a SOH value is determined which is lower than the previously determined SOH value, the current status under the method for the other type Ta of charging device 3a, according to the look-up table, is adjusted to the new or newly-determined SOH value (the look-up table value for the charge applied in Ah is adjusted thereto).

The user can thus alternate back-and-forth between the types of charging devices. The SOH value will nevertheless be calculated and adapted on the basis of, or by reference to both computing methods.

Display options are conceivable for the information Info, e.g. for the transmission or communication COM of the SOH value and the indication thereof on a display (e.g. on the processing device 2, for example on a steering wheel of a lawnmower or similar).

Moreover, an, in particular electrical, rated voltage of the battery pack 1, the processing device 2 and/or the charging device 3 is 36 V. In alternative exemplary embodiments, the rated voltage can be lower than or greater than 36 V, in particular 18 V or 72 V.

Additionally or alternatively, the, in particular, maximum drive power AL or charging power LL is at least 10 watts (W), particularly at least 100 W, particularly at least 1 kW (kilowatt), particularly at least 2 kW and/or no more than 10 kW, particularly no more than 5 kW, particularly 3 kW.

Further additionally or alternatively, the maximum, in particular electrical energy content, in particular the rated energy content of the battery pack 1 is at least 50 Wh (watt-hours), particularly at least 100 Wh, particularly at least 200 Wh and/or no more that 4,000 Wh, particularly no more than 2,000 Wh, particularly no more than 1,000 Wh and particularly no more than 500 Wh, particularly 337 Wh.

It is evident from the exemplary embodiments represented and described above that the invention provides an advantageous method and an advantageous system for the type-dependent determination of a state of health, or of a state variable corresponding to a state of health of a battery pack and, in particular, assumes the respectively improved properties thereof.

The foregoing disclosure has been set forth merely to illustrate the invention and is not intended to be limiting. Since modifications of the disclosed embodiments incorporating the spirit and substance of the invention may occur to persons skilled in the art, the invention should be construed to include everything within the scope of the appended claims and equivalents thereof.

What is claimed is:

1. A method for a type-dependent determination of a state of health or of a state variable corresponding to a state of health, of a battery pack for supplying an electrically powered processing device with electric drive power, wherein
the battery pack and a charging device are mutually coupleable for supplying the battery pack with the electric charging power, and
the charging device is from a set of different types of charging devices,
the method comprising:
a) recognizing a type of a coupled charging device, via the battery pack; and
b) determining the state of health or the state variable in dependence on the type recognized, via the battery pack.

2. The method according to claim 1, wherein step b) comprises:
determining the state of health or the state variable based on an at least intermittently supplied charging variable of a charge.

3. The method according to claim 2, further comprising:
detecting a charging current for the charging variable, via the charging device.

4. The method according to claim 3, wherein
determining the state of health or the state variable for the different types of charging devices is at least partially different.

5. The method according to claim 4, wherein
step b), for one type of the charging devices, comprises the following and, for another type, does not:
determining the state of health or the state variable based on the charging variable and a margin.

6. The method according to claim 5, wherein
the margin is a difference between state-of-charge variables temporally in advance of, and subsequent to, the supply of the charging variable in each case with a charging current reduction in the form of an absence of charging current.

7. The method according to claim 6, further comprising:
detecting a voltage for the state-of-charge variables and/or for the charging current reduction.

8. The method according to claim 7, further comprising:
for one type of the charging devices and not for another type of the charging devices:
stipulating the supply of charging power, for the reduction in the charging current, in dependence of the type recognized, and according to the voltage detected.

9. The method according to claim 1,
wherein the types included in a command structure are at least partially different, and/or
wherein recognition of a type comprises recognizing the command structure of the charging device, and/or
wherein the detected type is a recognized command structure.

10. The method according to claim 8, further comprising:
communicating, between the battery pack and the charging device, the charging variable, the charging current, the stipulation for the supply of the charging power, and/or a command from a command structure.

11. The method according to claim 10, wherein
the battery pack and the charging device comprise detachable electric power contacts for the supply of the charging power and detachable electric communication contacts for the communicating.

12. The method according to claim 1, further comprising:
saving the state of health determined or the state variable determined.

13. The method according to claim 7, further comprising:
saving the charging variable, the charging current detected, the state-of-charge variable, the voltage detected, and/or the type recognized.

14. The method according to claim 12, further comprising:
in an event of a newly-determined state of health or a newly-determined state variable which is greater than the saved state of health or the saved state variable, the saved state of health or saved state variable is not overwritten, and/or the newly-determined state of health or the newly-determined state variable is not saved.

15. The method according to claim 1, further comprising:
outputting user-perceptible information regarding either the determined state of health or the determined state variable, via the charging device and/or the processing device.

16. The method according to claim 10,
wherein execution of step a) is triggered by coupling, and/or
wherein step b), and the detection of the charging current, the voltage, the stipulation of the supply of charging power, the communication between the battery pack and the charging device, the saving of the determined state of health or the determined state variable, and/or the outputting of information, is executed a plurality of times.

17. A system for type-dependent determination of a state of health or a state variable corresponding to a state of health, of a battery pack for supplying an electrically powered processing device with electric drive power, wherein
the battery pack and a charging device are mutually coupleable for supplying the battery pack with electric charging power, and
the charging device is from a set of different types of charging devices,
wherein the system comprises:
a recognition device, wherein the recognition device is configured for recognizing a type of the coupled charging device, via the battery pack, and
a determination device, wherein the determination device is configured for determining the state of health or the state variable in dependence of the type thus recognized, via the battery pack.

18. The system according to claim 17, further comprising:
the battery pack, the charging device, and/or the processing device.
